(19) United States
(12) Patent Application Publication
(10) Pub. No.: US 2025/0263097 A1
(43) Pub. Date: Aug. 21, 2025

(54) Transport Vehicle and Transport Facility Including Transport Vehicle

(71) Applicant: Daifuku Co., Ltd., Osaka-shi (JP)

(72) Inventors: Tadashi Nishikawa, Hinocho (JP); Daichi Tomida, Hinocho (JP); Daisuke Ogawa, Hinocho (JP); Yoshitaka Deguchi, Hinocho (JP); Kenji Tamura, Hinocho (JP)

(21) Appl. No.: 19/053,569

(22) Filed: Feb. 14, 2025

(30) Foreign Application Priority Data
Feb. 16, 2024 (JP) 2024-022120

(51) Int. Cl. B61L 27/10; B61B 5/00; B61C 9/38; B61C 17/06; H01L 21/677

(52) U.S. Cl. CPC B61L 27/10; B61B 5/00; B61C 9/38; B61C 17/06; H01L 21/6773; H01L 21/67733; H01L 21/67736

(57) ABSTRACT

A holding unit of a transport vehicle is coupled to the travel unit via a coupling mechanism. The coupling mechanism is configured to be able to transition between a coupled state in which the travel unit and the holding unit are coupled to each other, and a separated state in which the travel unit and the holding unit are separated from each other. The travel unit executes both a coupled traveling mode of traveling while being coupled to the holding unit via the coupling mechanism and a separated traveling mode of traveling alone while being separated from the holding unit.

### CROSS-REFERENCE TO RELATED APPLICATION

This application claims priority to Japanese Patent Application No. 2024-022120 filed Feb. 16, 2024, the disclosure of which is hereby incorporated by reference in its entirety.

### BACKGROUND OF THE INVENTION

### Field of the Invention

The present invention relates to a transport vehicle and a transport facility including the transport vehicle.

### Description of Related Art

For example, JP 2022-177495A discloses a transport vehicle (1) that transports a transport object (200) between processes.

The transport vehicle (1) is configured to travel along a route (20) while holding the transport object (200). In other words, the transport vehicle (1) has both the function of traveling a route and the function of holding the transport object (200).

In such a technical field, for example, in a case where some sort of problem occurs in a transport vehicle during transport of a transport object, the transport vehicle may be forced to head to a maintenance station while holding the transport object. Alternatively, if a transport vehicle uses a power storage device installed therein as a power source and the remaining power is running low, the transport vehicle may be forced to head to a charging station or the like while holding the transport object. In situations as described above, the transport of the transport object will be interrupted, which would interfere with the normal operation of the transport vehicle.

### SUMMARY OF THE INVENTION

In view of the above-described circumstances, a technology that enables flexible operation of transport vehicles according to the situation is desired.

The technology to solve the foregoing problem is as follows.

A transport vehicle comprising:
a travel unit configured to travel along a rail; and
a holding unit configured to hold a transport object, the holding unit being configured to be coupled to the travel unit via a coupling mechanism,
the coupling mechanism being configured to transition between a coupled state in which the travel unit and the holding unit are coupled to each other, and a separated state in which the travel unit and the holding unit are separated from each other, and
the travel unit being configured to execute both a coupled traveling mode of traveling while being coupled to the holding unit via the coupling mechanism, and a separated traveling mode of traveling alone while being separated from the holding unit.

According to this configuration, by executing the coupled traveling mode, the travel unit can appropriately transport a transport object. Also, by executing the separated traveling mode, the travel unit can travel alone while separated from the holding unit. With this, during the execution of the separated traveling mode, the travel unit can perform another task at a location different from the location of the holding unit. Also, for example, if some sort of defect occurs only in the travel unit, the travel unit alone can take measures to resolve the defect, and the holding unit can be prevented from being involved. As described above, the present configuration enables flexible operation of the transport vehicle according to the situation.

Further features and advantages of the technology according to the present disclosure will become more apparent with the following illustrative and non-limiting description of embodiments, which will be described with reference to the drawings.

### BRIEF DESCRIPTION OF THE DRAWINGS

FIG. 1 is a schematic plan view showing a transport facility.

FIG. 2 is a side view showing a transport vehicle.

FIG. 3 shows an example of a switching process.

FIG. 4 is a diagram showing Modification 1.

FIG. 5 is a diagram showing Modification 1.

FIG. 6 is a diagram showing Modification 2.

FIG. 7 is a diagram showing Modification 3.

FIG. 8 is a diagram showing Modification 4.

### DESCRIPTION OF THE INVENTION

A transport vehicle and a transport facility including the transport vehicle, according to the present disclosure, can be used in semiconductor manufacturing plants, for example. In this case, examples of a transport object to be transported by the transport vehicle include a substrate container (so-called FOUP: Front Opening Unified Pod) that houses substrates (such as wafers and panels), and a reticle container (so-called reticle pod) that houses reticles. The following will describe embodiments of the transport vehicle and the transport facility including the transport vehicle, according to the present disclosure, with reference to the drawings.

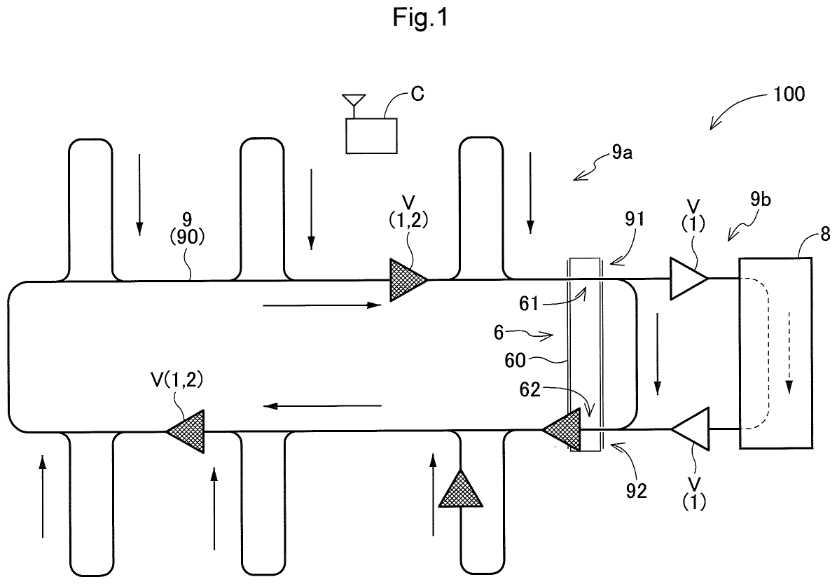

As shown in FIG. 1, a transport facility 100 includes transport vehicles V that travel on a travel path 9 and a control system C that controls the transport vehicles V. In the present embodiment, the transport facility 100 includes a plurality of transport vehicles V. The control system C is constituted by a high-level control device that manages the whole transport facility 100. However, the control system C may also include control devices included in the respective transport vehicles V.

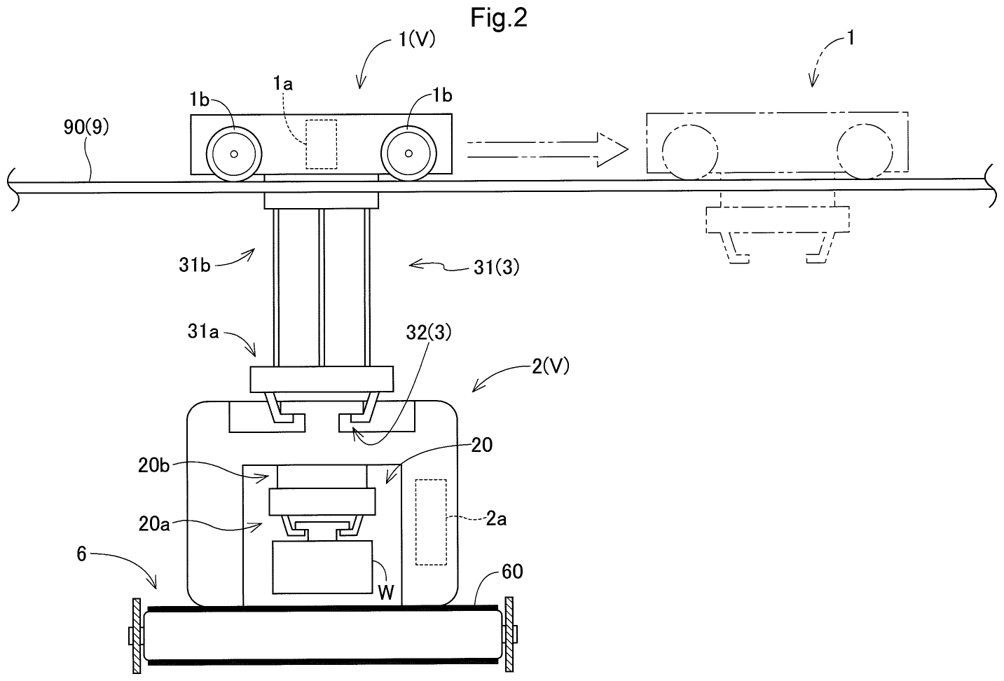

The travel path 9 is configured using a rail 90 (see FIG. 2). In other words, the transport facility 100 includes the rail 90. The transport vehicles V are configured as so-called overhead transport vehicles, which travel along the rail 90 installed in the vicinity of the ceiling.

In the present embodiment, the transport vehicles V are configured to travel on the travel path 9 in a predetermined direction. In other words, the travel path 9 is configured to allow only one-way travel of the transport vehicles V. However, temporary backward travel of the transport vehicles V may also be allowed on the travel path 9.

As shown in FIG. 2, each transport vehicle V includes a travel unit 1 that travels along the rail 90 and a holding unit 2 that holds a transport object W. The holding unit 2 is coupled to the travel unit 1 via a coupling mechanism 3. The moving route of the travel unit 1 traveling along the rail 90 and the moving route of the holding unit 2 coupled to the travel unit 1 do not overlap each other. In this example, the travel unit 1 is configured to move on the upper side of the rail 90. The holding unit 2 is configured to move on the lower side of the rail 90.

The coupling mechanism 3 is configured to be able to transition between a coupled state in which the travel unit 1 and the holding unit 2 are coupled to each other, and a separated state in which the travel unit 1 and the holding unit 2 are separated from each other.

The coupling mechanism 3 includes a travel unit-side coupling part 31 provided on the travel unit 1 and a holding unit-side coupling part 32 provided on the holding unit 2. At least one of the travel unit-side coupling part 31 and the holding unit-side coupling part 32 includes a coupling drive unit for the state transition of the coupling mechanism 3 between the coupled state and the separated state. In the present embodiment, this coupling drive unit is provided on the travel unit-side coupling part 31. Note however that a configuration is also possible in which the coupling drive unit is provided on the holding unit-side coupling part 32.

In the present embodiment, the travel unit-side coupling part 31 includes a grip mechanism 31a that grips the holding unit 2, and a lift mechanism 31b that moves the grip mechanism 31a up and down. The grip mechanism 31a constitutes at least a part of the above-mentioned coupling drive unit. For example, the grip mechanism 31a includes a pair of claws that move toward and away from each other, and a motor (not shown) that operates the pair of claws.

In the present embodiment, the holding unit-side coupling part 32 is a gripped part to be gripped by the grip mechanism 31a during the coupled state of the coupling mechanism 3. The holding unit-side coupling part 32 has a shape corresponding to the grip mechanism 31a. In this example, the holding unit-side coupling part 32 is flange-shaped so that the pair of claws of the grip mechanism 31a can appropriately grip the holding unit-side coupling part 32.

The travel unit 1 is configured to execute a coupled traveling mode of traveling while being coupled to the holding unit 2 via the coupling mechanism 3 and a separated traveling mode of traveling alone while being separated from the holding unit 2. In FIG. 2, the travel unit 1 executing the coupled traveling mode is indicated by solid lines, and the travel unit 1 executing the separated traveling mode is indicated by virtual lines.

In the present embodiment, the travel unit 1 includes a travel drive unit 1b and a power storage device 1a (hereinafter referred to as “travel unit-side power storage device 1a”) serving as a drive source of the travel drive unit 1b. The travel drive unit 1b is configured to be driven by power stored in the travel unit-side power storage device 1a. The travel drive unit 1b includes wheels and a motor (not shown). Note however that the travel drive unit 1b may also be constituted by a linear motor. The travel unit-side power storage device 1a is constituted by a battery or a capacitor, or by both of them.

The holding unit 2 is configured to move along the travel path 9 while being coupled to the travel unit 1. In other words, the holding unit 2 has a configuration such that it cannot travel alone while being separated from the travel unit 1.

The holding unit 2 is configured to hold the transport object W. Various modes of the holding unit 2 holding the transport object W can include a chuck type, a fork type, a conveyor type, and a loading type, for example.

In the present embodiment, the holding unit 2 includes a transfer unit 20 that transfers the transport object W to and from a transfer destination/origin (not shown). Examples of the transfer destination/origin include a load port, a buffer, a loading conveyor for loading transport objects W to an automated warehouse, and a discharge conveyor for discharging transport objects W from the automatic warehouse.

In the present embodiment, the transfer unit 20 includes a transfer grip part 20a that grips the transport object W and a transfer lift part 20b that lifts and lowers the transfer grip part 20a. With this, the transfer unit 20 is configured to transfer the transport object W to and from the transfer destination/origin.

In the present embodiment, the holding unit 2 includes a power storage device 2a (hereinafter referred to as “holding unit-side power storage device 2a”). The above-described transfer unit 20 is configured to be driven by power stored in the holding unit-side power storage device 2a at least in a state where the holding unit 2 is separated from the travel unit 1. The transfer unit 20 may be driven by power supplied from the travel unit 1 in a state where the holding unit 2 is coupled to the travel unit 1.

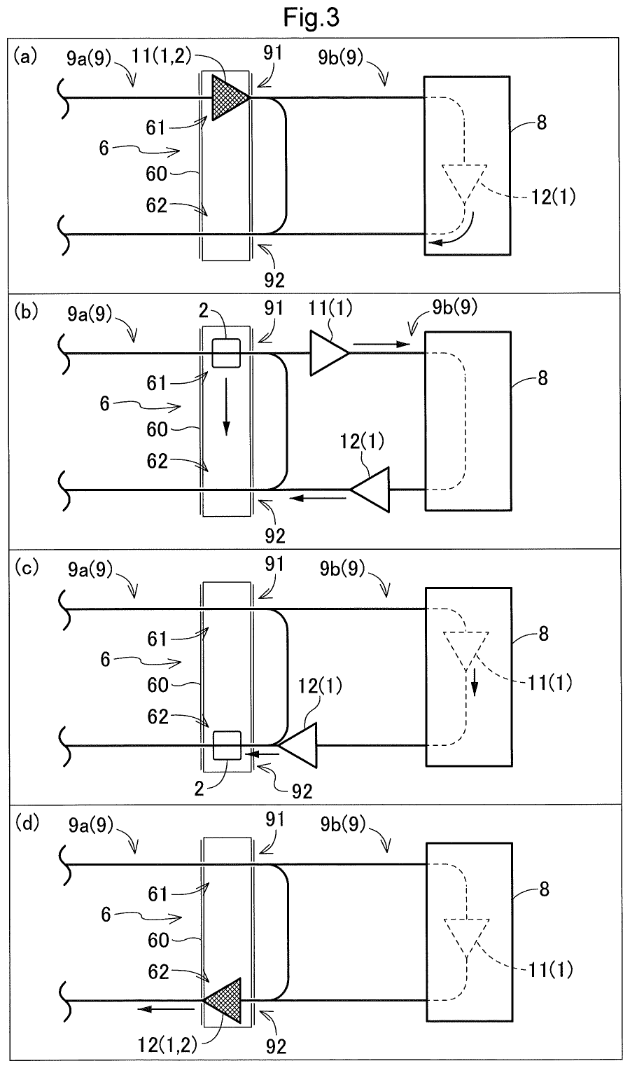

As shown in FIG. 1, in the present embodiment, the transport facility 100 includes a plurality of travel units 1. The transport facility 100 also includes a plurality of holding units 2. In this example, the number of travel units 1 present in the transport facility 100 is greater than the number of holding units 2. Note however that the numbers of these units may be equal to each other. Note that the symbols shown by triangles in FIGS. 1 and 3 each indicate a transport vehicle V, and specifically, a hatched triangle indicates a travel unit 1 coupled to a holding unit 2, and a white triangle indicates a single travel unit 1 separated from a holding unit 2.

The transport facility 100 includes a support area 6 where the holding unit 2 separated from the travel unit 1 is supported, and a power replenishment area 8 where at least one of charging and replacement of the travel unit-side power storage device 1a is performed. The power replenishment area 8 is provided along the rail 90.

The power replenishment area 8 includes at least one of a replacement device and a charging device. The replacement device is a device for replacing the travel unit-side power storage device 1a mounted on the travel unit 1. In this case, the travel unit 1 whose travel unit-side power storage device 1a has been replaced in the power replenishment area 8 can leave the power replenishment area 8 promptly. The charging device is a device for charging the travel unit-side power storage device 1a mounted on the travel unit 1. In this case, the travel unit 1 waits in the power replenishment area 8 until the travel unit-side power storage device 1a is completely charged. If a plurality of travel units 1 are being replenished with power in the power replenishment area 8, the travel unit 1 that has been completely replenished with power exits the power replenishment area 8 in order.

In the present embodiment, a transport apparatus 60 that transports the holding unit 2 is provided in the support area 6. In this example, the transport apparatus 60 is constituted by a conveyor that transports the holding unit 2 while supporting it from below. Note however that the transport apparatus 60 may be an AGV, a forklift, a crane, or the like.

The transport apparatus 60 is configured to transport the holding unit 2 between a receiving position 61, which is located corresponding to a first position 91 in the travel path 9 for the travel unit 1 extending along the rail 90 and at which the transport apparatus 60 receives the holding unit 2 from the travel unit 1, and a delivery position 62, which is located corresponding to a second position 92 in the travel path 9 and at which the transport apparatus 60 delivers the holding unit 2 to the travel unit 1.

In the present embodiment, the receiving position 61 is directly below the first position 91 in the travel path 9. The delivery position 62 is directly below the second position 92 on the travel path 9. In other words, the transport apparatus 60 receives the holding unit 2 from the travel unit 1 at the receiving position 61 while the travel unit 1 is located at the first position 91. The transport apparatus 60 delivers the holding unit 2 to the travel unit 1 at the delivery position 62 while the travel unit 1 is located at the second position 92. In other words, separation and coupling of the travel unit 1 and the holding unit 2 are performed in the support area 6. Note that the positional relationship between the first position 91 and the receiving position 61, and the positional relationship between the second position 92 and the delivery position 62 are not limited to the above-described positional relationships. These positional relationships need only be such that separation and coupling of the travel unit 1 and the holding unit 2 are possible.

In the present embodiment, the first position 91 is located upstream of the power replenishment area 8 along the travel path 9. The second position 92 is located downstream of the power replenishment area 8 along the travel path 9.

In the present embodiment, the travel path 9 includes a route 9a for transport along which the travel unit 1 travels to transport the transport object W, and a route 9b for replenishment that is a dedicated route for the travel unit 1 to travel for power replenishment. The above-described power replenishment area 8 is provided in the route 9b for replenishment. The route 9b for replenishment is branched off from the route 9a for transport and is merged into the route 9a for transport. In this example, the branching point at which the route 9b for replenishment is branched off from the route 9a for transport is located downstream of the first position 91. The merging point at which the route 9b for replenishment is merged into the route 9a for transport is located upstream of the second position 92.

As shown in FIG. 3, in the present embodiment, if it is determined that the amount of power stored in the travel unit-side power storage device 1a is a predetermined threshold or less, the control system C brings the coupling mechanism 3 into the separated state in response to the transport vehicle V being located at the position (first position 91 in this example) corresponding to the support area 6, so that the holding unit 2 is supported in the support area 6, and the travel unit 1 travels to the power replenishment area 8 in the separated traveling mode. With this, the travel unit 1 separated from the holding unit 2 can travel alone to the power replenishment area 8. Also, in the power replenishment area 8, the travel unit-side power storage device 1a is replaced or charged. Note that the above-mentioned threshold can be determined based on a percentage with respect to the maximum capacity of the travel unit-side power storage device 1a, or can also be determined as an absolute value that is independent of the maximum capacity of the travel unit-side power storage device 1a.

In the present embodiment, while the transport vehicle V is located at the first position 91, the control system C brings the coupling mechanism 3 into the separated state, so that the holding unit 2 is supported at the receiving position 61 by the transport apparatus 60. The control system C causes the transport apparatus 60 to transport the holding unit 2 from the receiving position 61 to the delivery position 62. In this way, the transport of the holding unit 2 is possible using a period of time for which the travel unit 1 is heading to the power replenishment area 8 alone, for example. The control system C brings the coupling mechanism 3 into the coupled state in response to the travel unit 1 being located at the second position 92, so that the holding unit 2 is coupled to the travel unit 1 at the delivery position 62. The travel unit 1 to which the holding unit 2 at the delivery position 62 is to be coupled may be the travel unit 1 that was previously separated from the holding unit 2 at the first position 91, or may be another travel unit 1.

The plurality of travel units 1 include a first travel unit 11 and a second travel unit 12, which is a travel unit 1 different from the first travel unit 11. In FIG. 3(a), the travel unit 1 executing the coupled traveling mode is defined as the first travel unit 11, and the other travel unit 1 preceding the first travel unit 11 is defined as the second travel unit 12.

As shown in FIG. 3(a), the travel unit 1 executing the coupled traveling mode, that is, the first travel unit 11 coupled to the holding unit 2, is stopped at the first position 91 in the travel path 9. In the shown example, the preceding second travel unit 12 is being replenished with power in the power replenishment area 8.

As shown in FIG. 3(b), the first travel unit 11 has separated from the holding unit 2 and has started the separated traveling mode. The first travel unit 11 having entered the route 9b for replenishment heads to the power replenishment area 8. The transport apparatus 60 receives the holding unit 2 from the first travel unit 11 at the receiving position 61 and transports the received holding unit 2 toward the delivery position 62. In the shown example, the second travel unit 12 has finished being replenished with power and has exited the power replenishment area 8.

As shown in FIG. 3(c), the holding unit 2 transported by the transport apparatus 60 reaches the delivery position 62. The first travel unit 11 that was separated from the holding unit 2 and reached the power replenishment area 8 is replenished with power in the power replenishment area 8. The second travel unit 12 travels in the vicinity of the second position 92 in the travel path 9.

As shown in FIG. 3(d), at the delivery position 62, the transport apparatus 60 delivers the holding unit 2 to the second travel unit 12 located at the second position 92 in the travel path 9. The second travel unit 12 is coupled to the holding unit 2 and starts the coupled traveling mode.

In the example shown in FIG. 3, the holding unit 2 initially coupled to the first travel unit 11 is separated from the first travel unit 11 and then is coupled to the second travel unit 12. Thus, in the present embodiment, the control system C is configured to be able to execute a switching process of switching the coupling target to which the holding unit 2 is to be coupled from the first travel unit 11 to the second travel unit 12. In the example shown in FIG. 3, the switching process involves the transport of the holding unit 2 by the transport apparatus 60.

Note however that the switching process is possible without the transport apparatus 60 transporting the holding unit 2. In this case, the control system C may couple the holding unit 2 that was separated from the first travel unit 11 located at the first position 91 and is supported at the receiving position 61, to the second travel unit 12 that is stopped at the first position 91 after the first travel unit 11 has left the first position 91. If the second travel unit 12 is located behind the first travel unit 11, the second travel unit 12 proceeds toward the first position 91, and is coupled to the holding unit 2 supported in the support area 6. On the other hand, if the second travel unit 12 is located ahead of the first travel unit 11, the first travel unit 11 is separated from the holding unit 2 and then travels backward so as to leave the first position 91, and the second travel unit 12 travels backward so as to be coupled to the holding unit 2 at the first position 91.

If no switching process is performed, the first travel unit 11 separated from the holding unit 2 at the first position is replenished with power in the power replenishment area 8, and after finishing the replenishment, the first travel unit 11 heads to the second position 92 and is coupled to the holding unit 2 at the second position 92.

When a sufficient amount of power remains in the travel unit-side power storage device la mounted on the first travel unit 11, the first travel unit 11 passes through the first position 91 and the second position 92 along the route 9a for transport, without heading to the power replenishment area 8.

### Modification 1

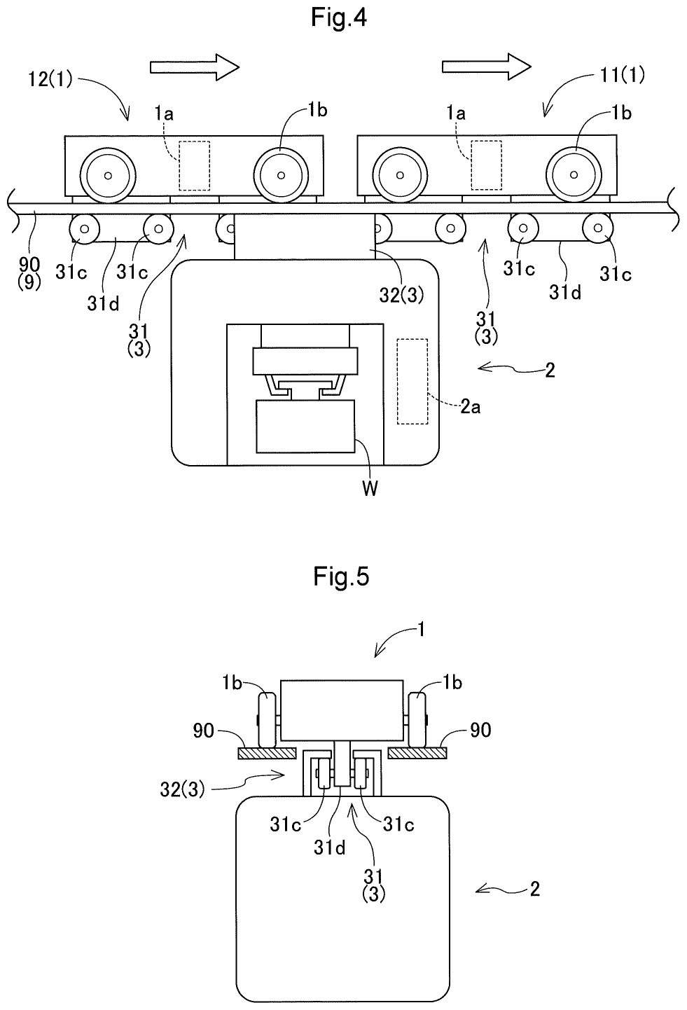

The following will describe Modification 1 with reference to FIGS. 4 and 5.

As shown in FIGS. 4 and 5, in Modification 1, the coupling mechanism 3 includes drive rollers 31c and a roller support part 31d that supports the drive rollers 31c in a manner such that they are rotatable. In this example, a plurality of drive rollers 31c and a plurality of roller support parts 31d (two roller support parts 31d in the shown example) are included in the travel unit-side coupling part 31.

In this example, the plurality of drive rollers 31c are aligned along the travel path 9. The plurality of drive rollers 31c are supported by the roller support part 31d with the rotation axis of each of the drive rollers 31c extending in a direction orthogonal to the travel path 9 as viewed in an up-down direction.

The roller support part 31d protrudes downward from the body of the travel unit 1. The plurality of drive rollers 31c are supported by the roller support part 31d below the rail 90.

The holding unit-side coupling part 32 is supported by the plurality of drive rollers 31c while the coupling mechanism 3 is in the coupled state. In this example, the holding unit-side coupling part 32 protrudes upward from the body of the holding unit 2 and is in contact with the plurality of drive rollers 31c from above while the coupling mechanism 3 is in the coupled state. In other words, in this example, the holding unit-side coupling part 32 is configured to be supported by the plurality of drive rollers 31c from below while the coupling mechanism 3 is in the coupled state.

The plurality of drive rollers 31c are controlled so as to be fixed (so as not to rotate) while supporting the holding unit-side coupling part 32.

In this example, in the switching process of switching the coupling target to which the holding unit 2 is to be coupled, the holding unit 2 is received and delivered between the travel unit-side coupling part 31 provided on the first travel unit 11 and the travel unit-side coupling part 31 provided on the second travel unit 12. In other words, the holding unit 2 is directly received and delivered between the first travel unit 11 and the second travel unit 12 without temporarily being supported in the support area 6 or the like. Such a switching process can also be referred to as a “direct switching process”.

In the direct switching process, the control system C positions the first travel unit 11 that is coupled to the holding unit 2 and is executing the coupled traveling mode, and the single second travel unit 12 that is executing the separated traveling mode, adjacent to each other on the travel path 9.

The control system C progressively shifts the state of the coupling mechanism 3 on the first travel unit 11 from the coupled state to the separated state, and progressively shifts the state of the coupling mechanism 3 on the second travel unit 12 from the separated state to the coupled state. The control system C realizes the state transition of the coupling mechanism 3 by driving and rotating the drive rollers 31c of the travel units 1.

In order for both the coupling mechanism 3 on the first travel unit 11 and the coupling mechanism 3 on the second travel unit 12 to make a state transition, the control system C causes the first travel unit 11 and the second travel unit 12 to travel in the same direction. For example, if the first travel unit 11 is located on the front side and the second travel unit 12 is behind the first travel unit 11, both the first and second travel units 11 and 12 are caused to travel forward.

During the state transition, if both the coupling mechanism 3 on the first travel unit 11 and the coupling mechanism 3 on the second travel unit 12 have an element in the “coupled state”, the holding unit-side coupling part 32 is supported by both the first travel unit 11 and the second travel unit 12 (the state shown in FIG. 4). From here, the state transition of the coupling mechanisms 3 is further advanced in both the first travel unit 11 and the second travel unit 12, and eventually the coupled state of the coupling mechanism 3 on the second travel unit 12 becomes dominant. Once the coupling mechanism 3 on the first travel unit 11 is completely separated and the coupling mechanism 3 on the second travel unit 12 is completely coupled, the direct switching process is complete.

Note that, in the description above, an example has been described in which the direct switching process is executed by moving the first travel unit 11 and the second travel unit 12 forward, but the direct switching process may also be executed by moving them backward.

Also, in the description above, an example has been described in which the direct switching process is executed by moving the first travel unit 11 and the second travel unit 12 forward or backward, but the direct switching process may also be executed in a state in which the first travel unit 11 and the second travel unit 12 are stopped. In this case, only the drive rollers 31c of the first travel unit 11 and the second travel unit 12 are rotated. With this, only the holding unit 2 moves between the stopped first and second travel units 11 and 12.

### Modification 2

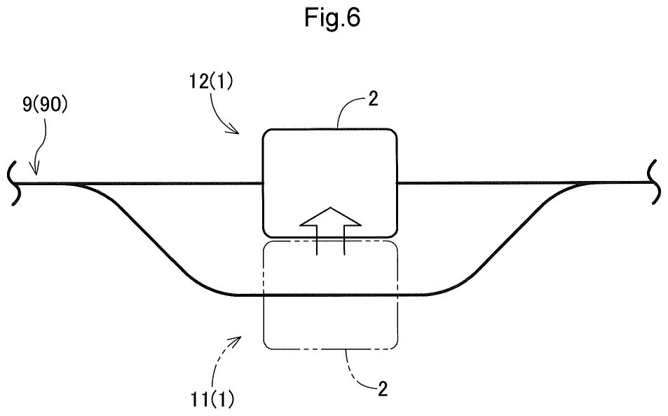

Next, Modification 2 will be described with reference to FIG. 6.

As shown in FIG. 6, in Modification 2, the control system C positions, in the direct switching process, the first travel unit 11 executing the coupled traveling mode and the second travel unit 12 executing the separated traveling mode, side by side on separate travel paths 9 disposed adjacent to each other in a parallel manner. In other words, the first travel unit 11 and the second travel unit 12 are positioned adjacent to each other along a direction orthogonal to the travel paths 9 as viewed in the up-down direction. Then, the control system C shifts the state of the coupling mechanism 3 on the first travel unit 11 from the coupled state to the separated state, and shifts the state of the coupling mechanism 3 on the second travel unit 12 from the separated state to the coupled state.

In the direct switching process in this example, only the holding unit 2 moves from the position corresponding to the first travel unit 11 to the position corresponding to the second travel unit 12 with the positions of the first and second travel units 11 and 12 fixed. As a result, the holding unit 2 transitions from the state of being coupled to the first travel unit 11 to the state of being coupled to the second travel unit 12, and then the direct switching process is complete.

Although detailed illustrations are omitted, in this example, the travel unit-side coupling part 31 on the second travel unit 12 includes a plurality of drive rollers 31c and a roller support part 31d that supports the plurality of drive rollers 31c in a manner such that they are rotatable, as in the above-described Modification 1. Note however that, in this example, the plurality of drive rollers 31c are aligned in a direction orthogonal to the travel path 9 as viewed in the up-down direction. Also, the plurality of drive rollers 31c are supported by the roller support part 31d with the rotation axis of each of the plurality of drive rollers 31c extending in a direction in which the travel path 9 extends. As a result, it is possible to move the holding unit 2 along a direction orthogonal to the travel path 9 as viewed in the up-down direction.

### Modification 3

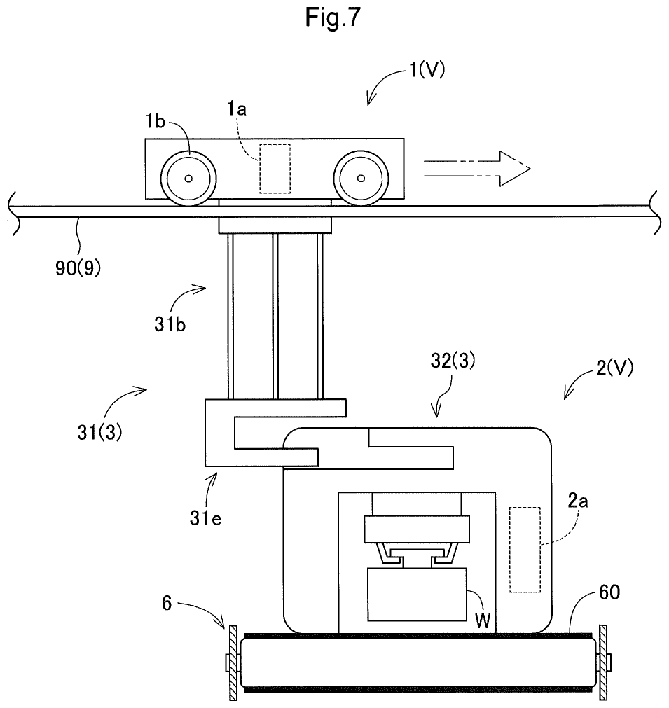

Next, Modification 3 will be described with reference to FIG. 7.

As shown in FIG. 7, in Modification 3, the travel unit-side coupling part 31 includes a hook 31e that engages with the holding unit-side coupling part 32. The hook 31e is configured to be lifted and lowered by the lift mechanism 31b.

In this example, the holding unit-side coupling part 32 is an engaged part to be engaged by the hook 31e while the coupling mechanism 3 is in the coupled state. The holding unit-side coupling part 32 has a shape corresponding to the hook 31e.

In this example, the separated state/coupled state of the coupling mechanism 3 is realized by a combination of the lifting/lowering operation of the hook 31e by the lift mechanism 31b and the forward/backward movement of the hook 31e caused by the forward/backward movement of the travel unit 1.

### Modification 4

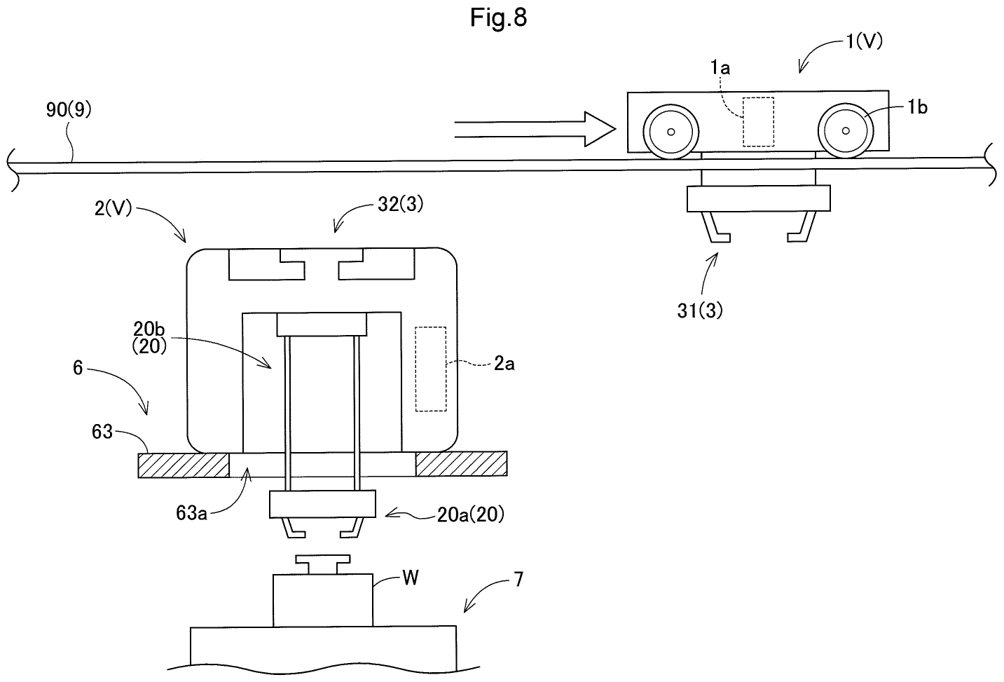

Next, Modification 4 will be described with reference to FIG. 8.

In this example, the holding unit 2 is configured to be able to execute both a coupled transfer mode of transferring the transport object W to and from a transfer destination/origin 7 while being coupled to the travel unit 1, and a separated transfer mode of transferring the transport object W to and from the transfer destination/origin 7 while being separated from the travel unit 1 and supported in the support area 6. FIG. 8 shows a situation where the holding unit 2 is executing the separated transfer mode. As described above, the transfer destination/origin 7 may be a load port, a buffer, a loading conveyor, a discharge conveyor, or the like.

The support area 6 includes a support part 63 that supports the holding unit 2. In this example, the support part 63 is constituted by a support platform that supports the holding unit 2 from below.

In this example, the support part 63 has an opening 63a through which the transport object W can pass in the up-down direction. The opening 63a may be a hole or a notch. Alternatively, if the support part 63 is constituted by a plurality of discontinuous members, e.g., a pair of plate members arranged at a distance from each other, a space between the pair of plate members may serve as the opening 63a.

In this example, the holding unit 2 executes the separated transfer mode while being supported by the support part 63. The holding unit 2 executes the separated transfer mode using the holding unit-side power storage device 2a as a power source of transfer unit 20. In the separated transfer mode, the holding unit 2 transfers the transport object W to and from the transfer destination/origin 7 located immediately below the support part 63 by lifting and lowering the transfer grip part 20a using the transfer lift part 20b. The transfer grip part 20a is passed through the opening 63a in the up-down direction, so as to be lifted and lowered over a range from the upper side of the support part 63 to the lower side of the support part 63.

In the description above, an example has been described in which the transfer destination/origin 7 is located immediately below the support part 63. However, the present invention is not limited to such an example, and the transfer destination/origin 7 and the support part 63 may be positioned in a manner such that they do not overlap with each other at least partially as viewed in a plan view. In this case, the transfer unit 20 may include, for example, a slide mechanism for moving the transport object W in a horizontal direction and a turning mechanism for changing the direction of the movement of the transport object W due to the slide mechanism. For example, the slide mechanism may include an arm or a fork.

In the description above, an example has been described in which the transfer unit 20 is powered by power stored in the holding unit-side power storage device 2a. However, the present invention is not limited to such an example, and a configuration is also possible in which, for example, a power supply device is provided in the support part 63, and the transfer unit 20 operates upon being supplied with power from this power supply device.

In the description above, an example has been described in which the support part 63 is configured to support the holding unit 2 from below. However, the present invention is not limited to such an example, and the support part 63 may be configured to suspend and support the holding unit 2 from above, for example. In this case, the above-mentioned opening 63a need not be formed in the support part 63.

### Other Modifications

In the description above, examples have been described in which the coupling mechanism 3 is of a gripping type, a roller type (Modifications 2 and 3), and a hook type (Modification 4), respectively. However, the coupling mechanism 3 may also employ other methods. For example, the coupling mechanism 3 may be of a magnet type. In this case, the travel unit-side coupling part 31 and the holding unit-side coupling part 32 are coupled to each other by the magnetic force of the magnet. Note that if the coupling mechanism 3 is of a magnet type, an electromagnet is preferably used. Accordingly, by controlling the state of a current flow through the electromagnet, the state transition between the separated state and the coupled state of the coupling mechanism 3 can be appropriately performed. Note that the coupling mechanism 3 may be constituted by a combination of some or all of the above-mentioned methods.

Note that the configurations disclosed in the above-described embodiments can be applied in combination with the configurations disclosed in other embodiments, as long as no contradiction arises. With respect to other configurations, the embodiments disclosed in the present specification are merely illustrative in all respects. Accordingly, various changes can be made as appropriate within the scope that does not depart from the gist of the present disclosure.

### Overview of the Present Embodiment

Hereinafter, overviews of the present embodiment will be described.

A transport vehicle includes:
a travel unit configured to travel along a rail; and
a holding unit configured to hold a transport object,
the holding unit being configured to be coupled to the travel unit via a coupling mechanism,
the coupling mechanism being configured to transition between a coupled state in which the travel unit and the holding unit are coupled to each other, and a separated state in which the travel unit and the holding unit are separated from each other, and
the travel unit being configured to execute both a coupled traveling mode of traveling while being coupled to the holding unit via the coupling mechanism, and a separated traveling mode of traveling alone while being separated from the holding unit.

According to this configuration, by executing the coupled traveling mode, the travel unit can appropriately transport a transport object. Also, by executing the separated traveling mode, the travel unit can travel alone while separated from the holding unit. With this, during the execution of the separated traveling mode, the travel unit can perform another task at a location different from the location of the holding unit. Also, for example, if some sort of defect occurs only in the travel unit, the travel unit alone can take measures to resolve the defect, and the holding unit can be prevented from being involved. As described above, the present configuration enables flexible operation of the transport vehicle according to the situation.

Preferably, a moving route of the travel unit traveling along the rail and a moving route of the holding unit coupled to the travel unit do not overlap each other.

According to this configuration, the travel unit and the holding unit can be prevented from interfering with each other.

Preferably, a transport facility including the foregoing transport vehicle includes:
a rail;
a support area in which the holding unit separated from the travel unit is supported; and
a control system configured to control the transport vehicle,
the travel unit including a travel drive unit, and a power storage device serving as a drive source of the travel drive unit, and
the transport facility further including a power replenishment area in which at least one of charging and replacement of the power storage device is performed, the power replenishment area being located along the rail.

According to this configuration, for example, in a case where the amount of power stored in the power storage device is a predetermined threshold or less or in another case, the holding unit separated from the travel unit can be appropriately supported in the support area, and at the same time, the travel unit separated from the holding unit can travel to the power replenishment area, where at least one of charging and replacement of the power storage device can be performed as appropriate.

Preferably, the transport facility further includes a transport apparatus in the support area and configured to transport the holding unit,
wherein the transport apparatus is configured to transport the holding unit between a receiving position at which the transport apparatus receives the holding unit from the travel unit, and a delivery position at which the transport apparatus delivers the holding unit to the travel unit, the receiving position being located corresponding to a first position in a travel path for the travel unit extending along the rail, and the delivery position being located corresponding to a second position in the travel path, and
the control system is configured to:
   bring the coupling mechanism into the separated state in response to the transport vehicle being located at the first position, so that the holding unit is supported at the receiving position by the transport apparatus;
   cause the transport apparatus to transport the holding unit from the receiving position to the delivery position; and
   bring the coupling mechanism into the coupled state in response to the travel unit being located at the second position, so that the holding unit located at the delivery position is coupled to the travel unit.

According to this configuration, the holding unit coupled to the travel unit can move along the travel path for the travel unit, and the holding unit separated from the travel unit can be moved along a route different from the travel path for the travel unit by the transport device. Therefore, according to this configuration, it is easy to increase flexibility in the operation of the facility.

Preferably, the transport vehicle is configured to travel along the travel path in a predetermined direction,
the first position is upstream of the power replenishment area along the travel path, and
the second position is downstream of the power replenishment area along the travel path.

According to this configuration, it is easy to separate the holding unit from the travel unit before the travel unit heads to the power replenishment area and to couple the holding unit to the travel unit after the travel unit exits the power replenishment area. It is also easy to simplify the travel path for the travel unit to realize such a configuration.

Preferably, a transport facility including the foregoing transport vehicle includes:
a control system configured to control the transport vehicle; and
a plurality of the travel units,
the plurality of travel units including a first travel unit, and a second travel unit different from the first travel unit, and
the control system being configured to execute a switching process of switching a coupling target, to which the holding unit is to be coupled, from the first travel unit to the second travel unit.

According to this configuration, the same holding unit can be transported by different travel units. Therefore, according to this configuration, it is easy to increase flexibility in the operation of the facility.

Preferably, the coupling mechanism includes a travel unit-side coupling part provided on the travel unit and a holding unit-side coupling part provided on the holding unit, and
in the switching process, the holding unit is received and delivered between the travel unit-side coupling part provided on the first travel unit and the travel unit-side coupling part provided on the second travel unit.

According to this configuration, the holding unit can be received and delivered between different transport vehicles in the travel path, without being temporarily supported in the support area or the like.

Preferably, a transport facility including the foregoing transport vehicle includes:
a support area in which the holding unit separated from the travel unit is supported,
the holding unit including a transfer unit configured to transfer the transport object to and from a transfer destination/origin, and
the holding unit being configured to execute both a coupled transfer mode of transferring the transport object to and from the transfer destination/origin while being coupled to the travel unit, and a separated transfer mode of transferring the transport object to and from the transfer destination/origin while being separated from the travel unit and supported in the support area.

According to this configuration, by executing the separated transfer mode, the holding unit separated from the travel unit can transfer the transport object.

### INDUSTRIAL APPLICABILITY

The technology according to the present disclosure is applicable to a transport vehicle and a transport facility including the transport vehicle.

What is claimed is:

1. A transport vehicle comprising:
a travel unit configured to travel along a rail; and
a holding unit configured to hold a transport object, and
wherein:
the holding unit is configured to be coupled to the travel unit via a coupling mechanism,
the coupling mechanism is configured to transition between a coupled state in which the travel unit and the holding unit are coupled to each other, and a separated state in which the travel unit and the holding unit are separated from each other, and
the travel unit is configured to execute both a coupled traveling mode of traveling while being coupled to the holding unit via the coupling mechanism, and a separated traveling mode of traveling alone while being separated from the holding unit.

2. The transport vehicle according to claim 1,
wherein a moving route of the travel unit traveling along the rail and a moving route of the holding unit coupled to the travel unit do not overlap each other.

3. A transport facility including the transport vehicle according to claim 1, the transport facility comprising:
a rail;
a support area in which the holding unit separated from the travel unit is supported; and
a control system configured to control the transport vehicle,
wherein the travel unit comprises a travel drive unit, and a power storage device serving as a drive source of the travel drive unit, and
wherein the transport facility further comprises a power replenishment area in which at least one of charging and replacement of the power storage device is performed, the power replenishment area located along the rail.

4. The transport facility according to claim 3, further comprising:
a transport apparatus in the support area and configured to transport the holding unit,
wherein the transport apparatus is configured to transport the holding unit between a receiving position at which the transport apparatus receives the holding unit from the travel unit, and a delivery position at which the transport apparatus delivers the holding unit to the travel unit, the receiving position located corresponding to a first position in a travel path for the travel unit extending along the rail, and the delivery position located corresponding to a second position in the travel path, and
wherein the control system is configured to:
bring the coupling mechanism into the separated state in response to the transport vehicle being located at the first position, so that the holding unit is supported at the receiving position by the transport apparatus;
cause the transport apparatus to transport the holding unit from the receiving position to the delivery position; and
bring the coupling mechanism into the coupled state in response to the travel unit being located at the second position, so that the holding unit located at the delivery position is coupled to the travel unit.

5. The transport facility according to claim 4,
wherein the transport vehicle is configured to travel along the travel path in a predetermined direction,
wherein the first position is upstream of the power replenishment area along the travel path, and
wherein the second position is downstream of the power replenishment area along the travel path.

6. A transport facility including the transport vehicle according to claim 1, the transport facility comprising:
a control system configured to control the transport vehicle; and
a plurality of the travel units,
wherein the plurality of travel units comprises a first travel unit, and a second travel unit different from the first travel unit, and
wherein the control system is configured to execute a switching process of switching a coupling target, to which the holding unit is to be coupled, from the first travel unit to the second travel unit.

7. The transport facility according to claim 6,
wherein the coupling mechanism comprises a travel unit-side coupling part provided on the travel unit and a holding unit-side coupling part provided on the holding unit, and
wherein in the switching process, the holding unit is received and delivered between the travel unit-side coupling part provided on the first travel unit and the travel unit-side coupling part provided on the second travel unit.

8. A transport facility including the transport vehicle according to claim 1, the transport facility comprising:
a support area wherein the holding unit separated from the travel unit is supported,
wherein the holding unit comprises a transfer unit configured to transfer the transport object to and from a transfer destination/origin, and
wherein the holding unit is configured to execute both a coupled transfer mode of transferring the transport object to and from the transfer destination/origin while being coupled to the travel unit, and a separated transfer mode of transferring the transport object to and from the transfer destination/origin while being separated from the travel unit and supported in the support area.
